(19) United States
(12) Patent Application Publication
(10) Pub. No.: US 2025/0218701 A1
(43) Pub. Date: Jul. 3, 2025

(54) ELECTRONIC DEVICE

(71) Applicant: XOOPAR LIMITED, New Territories (HK)

(72) Inventor: Ka Yin Tsui, New Territories (HK)

(21) Appl. No.: 18/746,020

(22) Filed: Jun. 17, 2024

(30) Foreign Application Priority Data
Jan. 3, 2024 (CN) 202420024504.6

(51) Int. Cl. H01H 9/02; G06F 3/044; H02J 50/00; H02J 50/10

(52) U.S. Cl. CPC H01H 9/0271; G06F 3/044; H02J 50/005; H02J 50/10; H01H 2231/052

(57) ABSTRACT

The invention discloses an electronic device, which comprises a supporting rod, a base, a functional component and a longitudinal touch control device, wherein the supporting rod is slender and is vertically arranged on the base; the functional component is connected with the supporting rod; and the touch control device is longitudinally arranged on the supporting rod and is electrically connected with the functional component so as to control the output power of the functional component by sensing a moving touch signal. When the electronic device of the invention is operated by a user, a finger is in sliding contact with the longitudinal touch control device on the supporting rod, so that stepless dimming, stepless sound tuning, stepless adjustment of the amount of mist and air output can be realized, and the flexibility and convenience of operation for adjusting the brightness/volume/amount of mist/air output are improved.

### CROSS REFERENCE TO RELATED APPLICATIONS

The present application claims the benefit of Chinese Patent Application No. 202420024504.6filed on Jan. 3, 2024, the contents of which are incorporated herein by reference in their entirety.

### BACKGROUND OF THE INVENTION

### 1.Technical Field

The invention relates to the technical field of electronics, in particular to an electronic device.

### 2. Description of Related Art

At present, the commonly used brightness adjustment methods of lamps such as desk lamps and night market lamps are mainly based on single-point touch control, for example, the switch of lamps and the brightness change of lights are controlled by single-point touch control. The single-point touch brightness adjustment method can only realize graded dimming, and the brightness of the lamp changes in a jumping, stepped or stepped manner, so the flexibility of brightness adjustment is not good, and the convenience of operation is not good.

Similarly, the volume adjustment mode of the currently commonly used sounding device is mainly a single-point touch control, for example, the switch of the sounding device is controlled in a single-point touch control mode, and the volume is changed. The volume adjustment mode of single-point touch can only realize hierarchical tuning, and the volume of the sound device changes in a jumping, dividing, or stepped manner, so the flexibility of volume adjustment is not good, and the convenience of operation is not good.

BRIEF SUMMARY OF THE INVENTION

The technical problem to be solved by the invention is to provide an improved electronic device.

The technical scheme adopted by the invention for solving the technical problems is as follows: an electronic device comprises a supporting rod, a base, a functional component and a longitudinal touch control device, wherein the supporting rod is slender and is vertically arranged on the base; the functional component is connected with the supporting rod. The touch control device is arranged on the supporting rod along the longitudinal direction and is electrically connected with the functional component so as to control the output power of the functional component through the sensed moving touch signal.

Preferably, the functional component comprises a first housing and a first circuit assembly arranged in the first housing, and the base comprises a second housing and a second circuit assembly arranged in the second housing;

The supporting rod is respectively connected with the first housing and the second housing;

The supporting rod is in a hollow tubular shape, and the second circuit assembly is electrically connected with the touch control device and the first circuit assembly respectively through wires penetrating through the supporting rod.

Preferably, the first circuit assembly comprises a functional element and a first control circuit electrically connected with the functional element, wherein the functional element comprises a light-emitting element, a sound generating element, an atomizing element or an air outlet element;

The first control circuit comprises a third control chip for receiving brightness control information or volume control information, and a control module electrically connected to the third control chip;

The second circuit assembly comprises a second control circuit, wherein the second control circuit comprises a first control chip and a second control chip which generate control information according to touch information; the first control chip and the second control chip are connected; the control information is brightness control information, volume control information, air volume control information or fog quantity control information;

The touch control device is provided with at least two groups of touch points, wherein the first group of touch points comprises a plurality of touch points which are respectively and electrically connected with the first control chip, and the second group of touch point comprises a plurality of touch points which are respectively and electrically connected with the second control chip;

The first control chip and the second control chip are electrically connected with the third control chip respectively.

Preferably, the first housing comprises a first upper housing and a first lower housing which are connected with each other; and one end of the supporting rod close to the first housing sequentially passes through the first lower housing and the first circuit assembly and then is connected with the first upper housing.

Preferably, the electronic device further comprises a wireless charging unit arranged in the second housing, wherein the wireless charging unit comprises a transmitting coil and a receiving coil which are arranged above the second circuit assembly at intervals.

Preferably, the base further comprises a base plate arranged in the second housing; the base plate comprises an upper surface and a lower surface, and the upper surface of the base plate is closer to the functional component than the lower surface; the transmitting coil is arranged on the lower surface of the base plate, and the receiving coil is arranged on the upper surface. The second circuit assembly is disposed between a lower surface of the base plate and the second housing.

Preferably, the touch control device comprises a capacitive touch panel.

Preferably, the supporting rod is hollow and tubular, and a mounting groove is formed on the wall of the supporting rod, and the touch control device is clamped and/or bonded to the mounting groove.

Preferably, the ratio of the length of the touch control device to the exposed length of the supporting rod is 60%-90%;

And/or the length of the touch control device is 160 mm-220 mm.

Preferably, the supporting rod is made of rigid material;

And/or the supporting rod is made of flexible material;

And/or the supporting rod is cylindrical, and the diameter of the supporting rod is 6-10 mm.

The invention at least has the following beneficial effects: when a user operates, the user can realize stepless dimming or stepless tuning through the sliding contact between the finger and the longitudinal touch control device on the supporting rod, thereby improving the flexibility of brightness/volume adjustment and the convenience of operation.

### BRIEF DESCRIPTION OF THE SEVERAL VIEWS OF THE DRAWINGS

The invention will be further described below in combination with the attached drawings and embodiments, in which:

FIG. 1 is a schematic structural diagram of an electronic device according to an embodiment of the present invention;

FIG. 2 is a vertical sectional structure diagram of the electronic device shown in FIG. 1;

FIG. 3 is a schematic diagram of a circuit structure of a second control circuit of the electronic device according to an embodiment of the present invention;

FIG. 4 is a sequence diagram of touch points distribution on a touch control device of an electronic device according to an embodiment of the present invention;

FIG. 5 is an electrical block diagram of an electronic device according to an embodiment of the present invention;

FIG. 6 is an exploded structural diagram of the electronic device shown in FIG. 1.

### DETAILED DESCRIPTION OF THE INVENTION

In order to have a clearer understanding of the technical features, purposes and effects of the invention, the specific embodiments of the invention are described in detail with reference to the drawings.

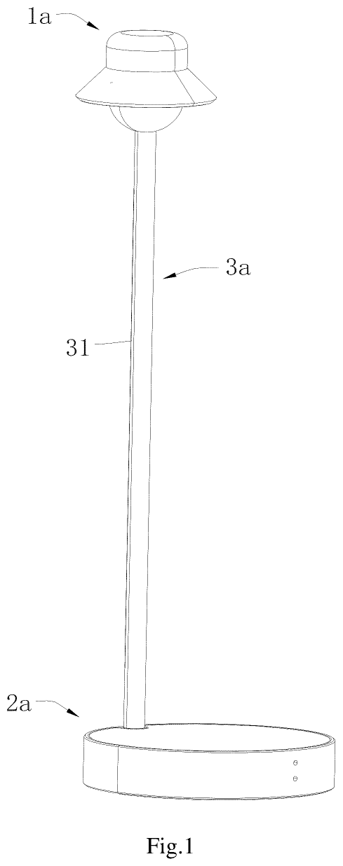

As shown in FIG. 1, an electronic device according to an embodiment of the present invention comprises a supporting rod 3a, a base 2a, a functional component 1a, and a longitudinal touch control device 31. The supporting rod 3a is slender and is vertically arranged on the base, and the functional component 1a is connected with the supporting rod 3a. The touch control device 31 is disposed on the supporting rod 3a along the longitudinal direction, and is electrically connected to the functional component 1a, so as to control the output power of the functional component 1a according to the sensed moving touch signal. The supporting rod 3a may be made of a rigid material such as metal or a flexible material such as a bendable rod.

It should be noted that the electronic device can be naturally placed on a horizontal placement surface (such as a horizontal desktop) when in use, and the direction perpendicular to the horizontal placement surface is called a longitudinal direction. Specifically, the touch control device 31 is used to slide and control the output power of the functional component 1a. The supporting rod 3a may be a longitudinal straight rod extending longitudinally, and the touch control device 31 is longitudinally disposed on the supporting rod 3a. A user may place a finger on the touch control device 31 and slide the finger back and forth longitudinally to change the output power of the functional component 1a.

In the embodiment shown in FIG. 1, the functional component 1a is a light-emitting device, and the touch control device 31 is electrically connected to the light-emitting device to control the output power of the light-emitting device, where the output power of the light-emitting device is represented by the brightness of the light-emitting apparatus from a user's perspective. In this case, the electronic device may be a small lamp.

It is understood that in other embodiments, the functional component 1a may also be a sound generating device, such as a speaker. The output power of the sound generating device is characterized by the volume of the sound generating by the sound generating device from the user's perspective. In this case, the electronic device may be a desktop audio.

It is understood that in other embodiments, the functional component 1a may also be an atomizing device. The output power of the atomizing device is characterized by the size of the atomizing quantity of the atomizing device from the user's perspective. In this case, the electronic device may be a small humidifier.

It is understood that in other embodiments, the functional component 1a may also be an air outlet device, such as a fan. The output power of the air outlet device is characterized by the magnitude of the air outlet volume of the air inlet device from the user's perspective. In this case, the electronic device may be a small fan.

When the electronic device of the present invention is in use, the user can slide the touch control device 31 on the supporting rod 3a in the longitudinal direction with a finger to change the output power of the functional component 1a. For example, the user can slide the touch control device 31 on the supporting rod 3a in the longitudinal direction with a finger to change the brightness of the light-emitting device, and the brightness of the light-emitting device can be continuously changed, so that the flexibility of brightness adjustment is better. Similarly, the user can slide the touch control device 31 on the supporting rod 3a in the longitudinal direction with a finger to change the volume of the sound generating device, and the volume of the sound generating device can be continuously changed, so that the flexibility of volume adjustment is better.

To sum up, the invention at least has the beneficial effects that when the user operates, the user can realize stepless dimming or stepless tuning through the sliding contact between the finger and the longitudinal touch control device 31 on the supporting rod 3a, which improves the flexibility of brightness/volume adjustment and the convenience of operation. Of course, when the functional component 1a is an atomizing device, stepless adjustment of the amount of atomizing quantity can also be realized; when the functional component 1a is an air outlet device, stepless adjustment of the amount of air output can also be realized. “Stepless dimming” refers to the smooth change and linear adjustment of brightness, and the stepless adjustment of volume, mist volume and air volume is the same.

In order to simplify the description, the embodiment when the functional component 1a is a light-emitting device is taken as a specific embodiment for reference in the following. When the functional component 1a is a sound generating device, it can be set by referring to the relevant technical features of the light-emitting device, and it is only necessary to replace the sound generating device with the light-emitting device and replace the brightness change with the volume change.

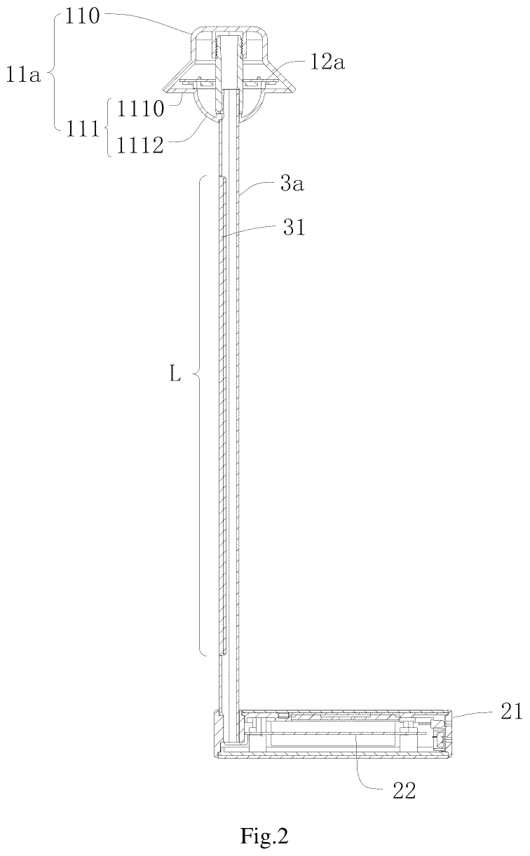

In the embodiment shown in FIG. 2, the functional component 1a comprises a first housing 11a and a first circuit assembly 12a disposed in the first housing 11a. Taking the functional component 1a as a light-emitting device as a specific embodiment for reference, the first circuit assembly 12a may comprise an LED light emitting element serving as a light source. Of course, in other embodiments, the light source is not limited to being an LED light emitting element. The first housing 11a is made of a transparent material, so that the light emitted from the first circuit assembly 12a can pass through the first housing 11a.

In the embodiment shown in FIG. 2, the base 2a comprises a second housing 21 and a second circuit assembly 22 disposed in the second housing 21. The supporting rod 3a is connected between the first housing 11a and the second housing 21 to connect the functional component 1a and the base 2a. The supporting rod 3a is provided with at least one touch control device 31. The touch control device 31 has a plurality of touch points electrically connected to the second circuit assembly 22 for the user to adjust the brightness of the light-emitting device by sliding.

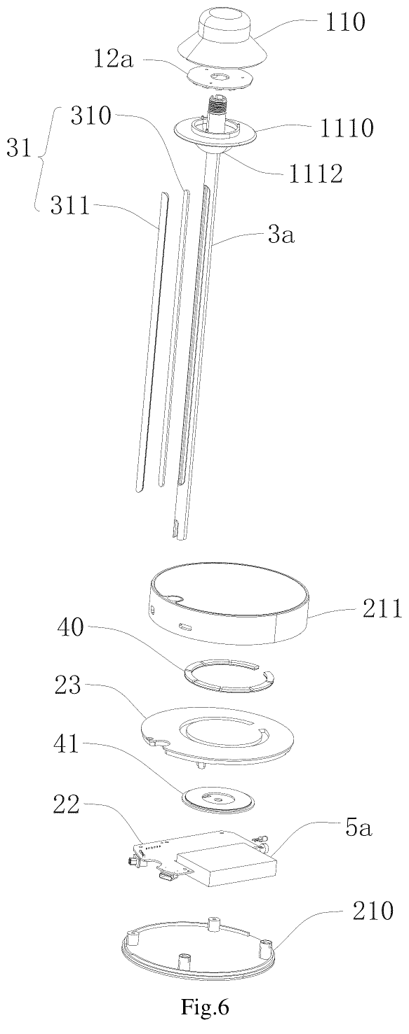

As shown in FIG. 6, in an embodiment, the supporting rod 3a is hollow and tubular, and can be used for threading one or more wires (not shown). The supporting rod 3a is respectively connected to the first housing 11a and the second housing 21, and the second circuit assembly 22 is respectively electrically connected to the touch control device 31 and the first circuit assembly 12a through one or more wires passing through the interior of the supporting rod 3a, so as to implement electrical signal transmission among the touch control device 31, the second circuit assembly 22, and the first circuit assembly 12a. The electrical signal flows from the touch control device 31 to the second circuit assembly 22 and then to the first circuit assembly 12a.

When the electronic device is a lamp, the user can slide the touch control device 31 on the supporting rod 3a with a finger, and the second circuit assembly 22 receives an electrical signal sent by the touch control device 31 and sends a corresponding electrical signal to the first circuit assembly 12a, so that the first circuit assembly 12a controls the brightness of the LEDs to change. For example, when a finger slides on the touch control device 31 along a first direction, the brightness of the light-emitting device is gradually increased; conversely, when the finger slides on the touch control device 31 along a second direction (opposite to the first direction), the brightness of the light-emitting device is gradually decreased. Therefore, the user only needs to slide the touch control device 31 on the supporting rod 3a back and forth to realize the brightness adjustment of the light-emitting device, which is easy to operate and has a good user experience.

One end of the supporting rod 3a close to the functional component 1a can partially extend into the first housing 11a. One end of the supporting rod 3a close to the base 2a may also partially extend into the second housing 21. Therefore, in some embodiments, the overall length of the supporting rod 3a may be greater than its exposed length, which is the difference between its overall length and the length extending into the first housing 11a and/or the length extending into the second housing 21. The exposed length of the supporting rod 3a is a length that can be measured in a natural state of the electronic device.

In the embodiment shown in FIG. 1 and FIG. 2, the length L of the touch control device 31 is less than the length of the supporting rod 3a, but the length L of the touch control device 31 should not be too small considering the user's touch experience. In some embodiments, the ratio of the length L of the touch control device 31 to the exposed length of the supporting rod 3a may be 60% to 90%, that is, the ratio of the length L of the touch control device 31 to the exposed length of the supporting rod 3a may be 60%, 90%, or any value between 60% and 90%. And then, the touch control device 31 occupies most of the area of the entire exposed length of the supporting rod 3a, and the user can easily control the output power of the functional component 1a when the user's fingers move on the supporting rod 3a, which is more convenient to operate and gives a better experience. That is, the user only needs to touch the supporting rod 3a to quickly locate the position of the touch control device 31, which can bring a convenient experience of “blind adjustment of brightness”. Moreover, the touch control device 31 has a sufficient length on the supporting rod 3a, so that more touch points can exist, the span between the maximum brightness and the minimum brightness can be larger, and the brightness adjustment can be more accurate.

In some embodiments, the length of the touch control device 31 may be 160 mm to 220 mm, so as to provide a long enough operation space for the user without intentionally searching for the position of the touch control device 31. Specifically, the length L of the touch control device 31 may be 160 mm, 220 mm, or any value between 160 mm and 220 mm. In some embodiments, the exposed length of the supporting rod 3a is slightly greater than 220 mm.

In the embodiment shown in FIG. 1 and FIG. 2, in order to provide a good touch experience when the user touches the supporting rod 3a, the supporting rod 3a may be elongated, and then, the user may gently hold the supporting rod 3a with a thumb and a forefinger and move up and down, thereby generating a touch signal. Specifically, the brightness can be controlled to increase when the finger moves from bottom to top, and the brightness can be controlled to decrease when the finger moves from top to bottom. It is very convenient to operate, and the user experience is better. It is understandable that, it can also be set to control the brightness to decrease when the finger moves from bottom to top, and to increase when it moves from top to bottom. It is also understandable that when the functional component 1a is a sounding unit, the volume can be controlled by sensing the up and down touch movement of a finger.

In some embodiments, the supporting rod 3a may be cylindrical and have a diameter of 6 mm to 10 mm. And then, the user's touch action is very comfortable and the experience is good. Specifically, the diameter of the supporting rod 3a is 6 mm, 10 mm, or any value between 6 mm and 10 mm.

In some embodiments, the supporting rod 3a may be made of rigid material, that is, the supporting rod 3a is a rigid supporting rod, and in other embodiments, the supporting rod 3a may be made of flexible material, that is, the supporting rod 3a is flexible supporting rod.

In an embodiment, the touch control device 31 comprises a capacitive touch panel, but the touch control device 31 is not limited to including a capacitive touch panel, and may also comprise a resistive touch panel.

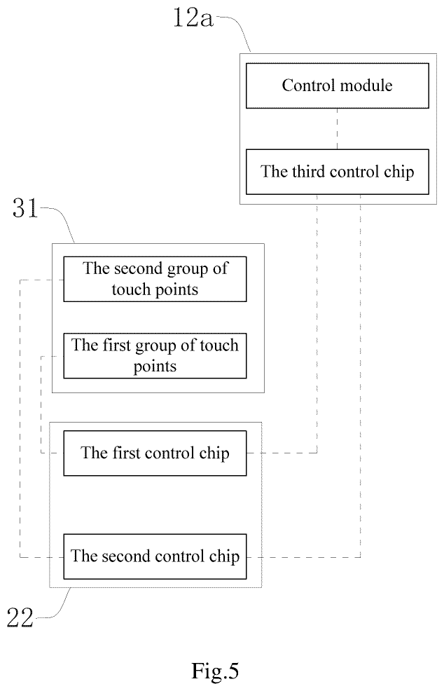

As shown in FIG. 5, the first circuit assembly 12a may comprise a functional element and a first control circuit electrically connected to the functional element. The functional element may be a light-emitting element, a sound generating element, an atomizing element, a blower, etc. The first control circuit comprises a third control chip and a control module electrically connected with the third control chip. The third control chip is used for receiving control information and sending PWM signals to the control module according to the control information, and the control module controls the output power of the functional element according to the PWM signals. Corresponding to different functional elements, the control information may be brightness control information, volume control information, air output control information or atomizing quantity control information.

For example, when the functional component 1a is a light-emitting device, the control module is a light brightness control module. When the functional component 1a is a sound generating device, the control module is a volume control module. When the functional component 1a is an atomizing device, the control module is an atomizing quantity control module. When the functional component 1a is an air outlet device, the control module is an air outlet volume control module. The light brightness control module may refer to a light brightness control circuit in the prior art, for example, a circuit structure for adjusting the brightness of an LED light-emitting element; similarly, the volume control module may refer to a volume control circuit in the prior art, for example, a circuit structure for adjusting the volume of a speaker. In the same way, the atomizing quantity control module may refer to the atomizing quantity control circuit inside the humidifier in the prior art; in the same way, the air output control module may refer to the air output control circuit inside the fan in the prior art. The light brightness control circuit, the volume control circuit, the atomizing quantity control circuit inside the humidifier, and the air output control circuit inside the fan are mature existing technologies, and will not be described here.

As shown in FIG. 3 and FIG. 5, in an embodiment, the second circuit assembly 22 may comprise a second control circuit, and the second control circuit comprises a first control chip U1 and a second control chip U2, and a first capacitor C1 and a second capacitor C2. The first control chip U1 is connected to the second control chip U2.

Specifically, as shown in FIG. 3, PIN 1 of the first control chip U1 is used to receive SCL signal. PIN 2 of the first control chip U1 is used to receive SDA signal. PIN 6 of the first control chip U1 is used to receive U1CSIO1 signal. PIN 7 of the first control chip U1 is used to receive U1CSIO0 signal. PIN 8 of the first control chip U1 is used to receive U1CSIO3 signal. PIN 9 of the first control chip U1 is used to receive U1CSIO4 signal. The first control chip U1 is connected to the first capacitor C1 by its pin 4, grounded by its pins 3 and 5, and connected to the second control chip U2 by its pin 10.

PIN 1 of the second control chip U2 is used to receive SCL signal. PIN 2 of the second control chip U2 is used to receive SDA signal, PIN 3 of the second control chip U2 is used to receive U2CSIO2 signal, PIN 6 of the second control chip U2 is used to receive U2CSIO1 signal. PIN 7 of the second control chip U2 is used to receive U2CSIO0 signal, PIN 8 of the second control chip U2 is used to receive U2CSIO3 signal. PIN 9 of the second control chip U2 is used to receive U2CSIO4 signal. The second control chip U2 is connected to the second capacitor C2 by its pin 4, grounded by its pin 5, and connected to the first control chip U1 by its pin 10.

When the functional component 1a is a light-emitting device, the first control chip U1 and the second control chip U2 may generate brightness control information according to the touch information. When the functional component 1a is a sound generating device, the first control chip U1 and the second control chip U2 may generate volume control information according to the touch information. That is, the first control chip U1 and the second control chip U2 serve as intermediate control elements between the touch control device 31 and the functional component 1a.

At the input ends of the first control chip U1 and the second control chip U2, the first control chip U1 and the second control chip U2 are connected to the touch control device 31 and receive touch information.

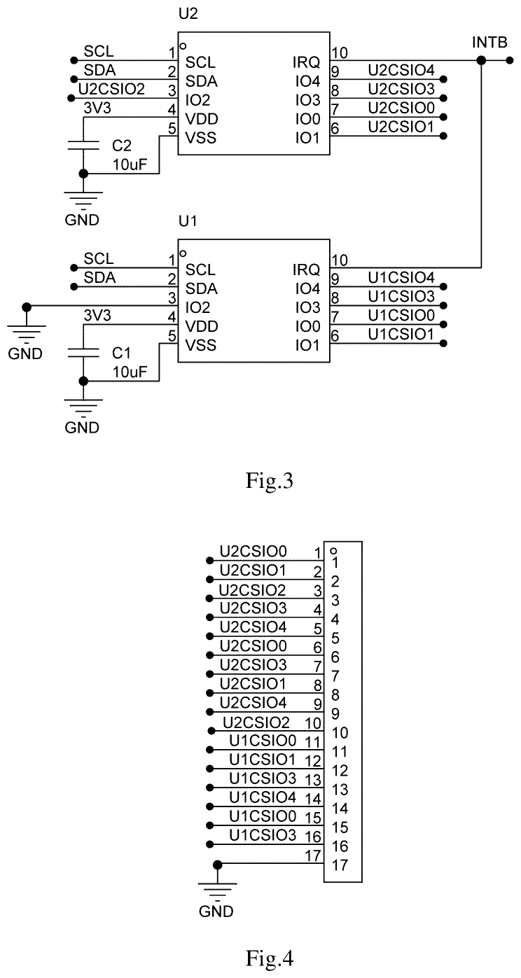

As shown in FIG. 4, in an embodiment, two groups of touch points are disposed on the touch control device 31. The first group of touch points comprises a plurality of touch points electrically connected to the first control chip U1 respectively, and the touch points are touch information sent by the first control chip U1. The second group of touch points comprises a plurality of touch points respectively electrically connected to the second control chip U2, and the touch points send touch information to the second control chip U2.

Specifically, the first group of touch points comprises Touch Point 11 (U1CSIO0), Touch Point 12 (U1CSIO1), Touch Point 13 (U1CSIO3), Touch Point 14 (U1CSIO4), and Touch Point 15 (U1CSIO0) and Touch Point 16 (U1CSIO3);

The second group of touch points comprises Touch Point 1 (U2CSIO0), Touch Point 2 (U2CSIO1), Touch Point 3 (U2CSIO2), Touch Point 4 (U2CSIO3), Touch Point 5 (U2CSIO4), Touch Point 6 (U2CSIO0), Touch Point 7 (U2CSIO3)), Touch Point 8 (U2CSIO1), Touch Point 9 (U2CSIO4), and Touch Point 10 (U2CSIO2);

Touch Point 1 (U2CSIO0), Touch Point 2 (U2CSIO1), Touch Point 3 (U2CSiO2), Touch Point 4 (U2CSIO3), Touch Point 5 (U2CSIO4), Touch Point 6 (U2CSIO0), Touch Point 7 (U2CSIO3), Touch Point 8 (U2CSIO1), Touch Point 9 (U2CSIO4), Touch Point 10 (U2CSIO2), Touch Point 11 (U1CSIO0), Touch Point 12 (U1CSIO1), Touch Point 13 (U1CSIO3), Touch Point 14 (U1CSIO4), Touch Point 15 (U1CSIO0) and Touch Point 16 (U1CSIO3) are arranged in order along the longitudinal direction of the supporting rod 3a.

Taking the functional component 1a as a light-emitting device as an example, the first control chip U1 and the second control chip U2 are respectively electrically connected to the third control chip at the output ends of the first control chip U1 and the second control chip U2. When the first control chip U1 and the second control chip U2 receive touch information from various touch points, they generate brightness control information and send it to the third control chip. Subsequently, the third control chip sends a corresponding PWM signal to the light brightness control module, and the light brightness control module controls the brightness of the LEDs of the first circuit assembly 12a to change.

To sum up, referring to FIG. 2 and FIG. 5, a specific implementation process of adjusting the brightness by touch control is as follows:

When a user puts a finger on the touch control device 31, one or more touch points touched on the touch control device 31 will trigger a high level signal under the action of the distributed capacitance of the human body, and the first control chip U1 and the second control chip U2 receive the signal to determine the movement sequence of the finger on each touch point. A corresponding brightness control signal is generated corresponding to the moving sequence and sent to the third control chip, the third control chip sends a corresponding PWM signal (for example, a signal for lighting up or dimming the light) to the light brightness control module, and the light brightness control module controls the LED light-emitting elements of the first circuit assembly 12a to be brightened or dimmed.

That is, the touch control device 31 is electrically connected to the functional component 1a indirectly through the second circuit assembly 22, so as to control the output power of the functional component 1a according to the sensed moving touch signal (a signal triggered by a human hand sliding and touching the touch control device 31).

In the embodiment shown in FIG. 6, the pipe wall of the supporting rod 3a is provided with a mounting groove, and the touch control device 31 is clamped and/or adhered to the mounting groove. That is, the mounting grooves of the touch control device 31 and the supporting rod 3a may be clamped, and the touch control device 31 and the mounting grooves of the supporting rod 3a may be relatively fixed together in an interference fit manner or relatively fixed together in a protrusion and groove fit manner. Alternatively, the touch control device 31 and the mounting groove of the supporting rod 3a may be bonded together. In this case, the touch control device 31 and the mounting groove of the supporting rod 3a may be bonded together by glue. Alternatively, the mounting grooves of the touch control device 31 and the supporting rod 3a may be clamped and then adhered together by glue for reinforcement.

Further, in the embodiment shown in FIG. 6, the touch control device 31 comprises a PCB 310 clamped on the mounting groove of the supporting rod 3a, and a protective layer 311 covering the PCB 310. The protective layer 311 may be an insulating member such as glass. The PCB 310 is connected with the wires in the supporting rod 3a, and the wires in the supporting rod 3a also extend along the length direction of the supporting rod 3a and are respectively connected with the second circuit assembly 22 and the first circuit assembly 12a. Thereby realizing the transmission of electrical signals between the first group of touch points and the first control chip U1, the transmission of electrical signals between the second group of touch points and the second control chip U2, and the transmissions of electrical signals among the first control chip U1, the second control chip U2, and the third control chip.

In the embodiment shown in FIG. 6, the electronic device further comprises a wireless charging unit disposed in the second housing 21. The wireless charging unit comprises a transmitting coil 41 and a receiving coil 40 spaced above the second circuit assembly 22. The wireless charging unit can be used for placing an electronic device such as a mobile phone or an earphone on the base 2a for wireless charging.

Further, in the embodiment shown in FIG. 6, the base 2a further comprises a base plate 23 disposed in the second housing 21. The base plate 23 comprises an upper surface and a lower surface, and the upper surface of the base plate 23 is closer to the light-emitting device than the lower surface thereof. The transmitting coil 41 is provided on the lower surface of the base plate 23, and the receiving coil 40 is provided on the upper surface of the base plate 23.

The second circuit assembly 22 is disposed between the lower surface of the base plate 23 and the second housing 21. Specifically, the second housing 21 comprises a second upper housing 211 and a second lower housing 210, the second upper housing 211 and the second lower housing 210 enclose a receiving space, and the second circuit assembly 22 is disposed in the receiving space and located between the lower surface of the base plate 23 and the second lower housing 210.

Further, in the embodiment shown in FIG. 6, the electronic device further comprises a battery 5a disposed in the second housing 21. The battery 5a is connected to the second circuit assembly 22 and located between the lower surface of the base plate 23 and the second lower housing 210.

In the embodiment shown in FIG. 6, the first housing 11a comprises a first upper housing 110 and a first lower housing 111. The end of the support rod 3a near the first housing 11a passes through the first lower housing 111, the first circuit component 12a in sequence, and is connected to the first upper housing 110. Specifically, in this embodiment, both the first lower housing 111 and the first circuit assembly 12a are provided with a central through hole through which the supporting rod 3a passes. The first lower housing 111 comprises a disc body 1110 and a hemisphere 1112 connected to the disc body. The first upper housing 110 has a straw hat shape. The first circuit assembly 12a has a disk shape. The first circuit assembly 12a is sandwiched and fixed between the disc body and the first upper housing 110. One end of the supporting rod 3a close to the first housing 11a is provided with a thread, and the surface of the first upper housing 110 facing the first lower housing 111 is also provided with a thread, so that one end of the supporting rod 3a close to the first housing 11a can be detachably connected with the first upper housing 110.

When the functional component 1a is an atomizing device, a mist outlet (not shown) may also be provided on the first housing 11a, so that the mist generated by the atomizing element in the first housing 11a is sent out through the mist outlet. Similarly, when the functional component 1a is an air outlet device, an air outlet (not shown) may be provided on the first housing 11a, so that the air flow generated by the fan in the first housing 11a is sent out through the air outlet.

It can be understood that the above embodiments only express the preferred embodiments of the invention, and the description is more specific and detailed, but it cannot be understood as a limitation to the patent scope of the invention. It should be noted that, for those of ordinary skill in the art, the above technical features can be freely combined, and a number of modifications and improvements can be made without departing from the concept of the invention, all of which fall within the scope of protection of the invention. Therefore, all equivalent transformations and modifications made in the scope of the claims of the invention shall be covered by the claims of the invention.

What is claimed is:

1. An electronic device, comprising a supporting rod (3a), a base (2a), a functional component (1a) and a longitudinal touch control device (31), wherein the supporting rod (3a) is slender and is erected on the base (2a); the functional component (1a) is connected to the supporting rod (3a); the touch control device (31) is longitudinally arranged on the supporting rod (3a) and is electrically connected to the functional component (1a), so as to control the magnitude of the output power of the functional component (1a) through the sensed moving touch signal.

2. The electronic device according to claim 1, wherein the functional component (1a) comprises a first housing (11a) and a first circuit assembly (12a) arranged in the first housing (11a), the base (2a) comprises a second housing (21) and a second circuit assembly (22) disposed in the second housing (21);
the supporting rod (3a) is connected to the first housing (11a) and the second housing (21) respectively;
the supporting rod (3a) is a hollow tubular shape, and the second circuit assembly (22) is electrically connected to the touch control device (31) and the first circuit assembly (12a) respectively through wires passing through the interior of the supporting rod (3a).

3. The electronic device according to claim 2, wherein the first circuit assembly (12a) comprises a functional element and a first control circuit electrically connected to the functional element, wherein the functional element comprises a light-emitting element, a sound generating element, an atomizing element or an air outlet element;
the first control circuit comprises a third control chip for receiving control information, and a control module electrically connected to the third control chip;
the second circuit assembly (22) comprises a second control circuit, and the second control circuit comprises a first control chip (U1) and a second control chip (U2) that generate the control information according to the touch information, wherein the first control chip (U1) and the second control chip are connected; the control information is brightness control information, volume control information, air output quantity control information or atomizing quantity control information; the touch control device (31) is provided with at least two groups of touch points, the first group of touch points comprising a plurality of touch points respectively electrically connected with the first control chip (U1), the second group of touch point comprising a plurality of touch point respectively electrically connected with the second control chip (U2);
the first control chip (U1) and the second control chip (U2) are electrically connected to the third control chip respectively.

4. The electronic device according to claim 2, wherein the first housing (11a) comprises a first upper housing (110) and a first lower housing (111) connected to each other; one end of the supporting rod (3a) close to the first housing (11a) passes through the first lower housing (111) and the first circuit assembly (12a) in sequence and then is connected to the first upper housing (110).

5. The electronic device according to claim 2, wherein the electronic device further comprising a wireless charging unit disposed in the second housing (21), wherein the wireless charging unit comprises a transmitting coil (41) and a receiving coil (40) spaced above the second circuit assembly (22).

6. The electronic device according to claim 5, wherein the base (2a) further comprises a base plate (23) arranged in the second housing (21); the base plate (23) comprises an upper surface and a lower surface, and the upper surface of the base plate (22) is closer to the functional component (1a) than the lower surface thereof; the transmitting coil (41) is arranged on the lower surface of the base plate (23), the receiving coil (40) is arranged on the upper surface of the base plate (23), and the second circuit assembly (22) is arranged between the lower surface of the base plates (23) and the second housing (21).

7. The electronic device according to claim 1, wherein the touch control device (31) comprises a capacitive touch panel.

8. The electronic device according to claim 1, wherein the supporting rod (3a) is in a hollow tubular shape, an installation groove is formed on the wall of the supporting rod (3a), and the touch control device (31) is clamped and/or adhered to the installation groove.

9. The electronic device according to claim 1, wherein a ratio of a length (L) of the touch control device (31) to an exposed length of the supporting rod (3A) is 60%-90%; and/or
the length (L) of the touch control device (31) is 160-220 mm.

10. The electronic device according to claim 1, wherein the supporting rod (3a) is made of rigid material; and/or
the supporting rod (3a) is made of flexible material; and/or
the supporting rod (3a) is cylindrical and has a diameter of 6 mm to 10 mm.
